(19) United States
(12) Patent Application Publication
(10) Pub. No.: US 2015/0131353 A1
(43) Pub. Date: May 14, 2015

(54) POWER SUPPLY DEVICE

(71) Applicant: Kabushiki Kaisha Toshiba, Tokyo (JP)

(72) Inventor: Yuji Nakajima, Nishitama-gun (JP)

(21) Appl. No.: 14/338,173

(22) Filed: Jul. 22, 2014

(30) Foreign Application Priority Data
Nov. 11, 2013 (JP) 2013-233345

(51) Int. Cl. H05K 7/20

(52) U.S. Cl. CPC H05K 7/2039
USPC 363/141

(57) ABSTRACT

According to one embodiment, a power supply device includes a main circuit board including a switching circuit, a transformer board opposite the main circuit board and including a transformer, and an intermediate cooling plate between the main circuit board and the transformer board and configured to cool at least one of a heat-producing element of the switching circuit and the transformer.

### CROSS-REFERENCE TO RELATED APPLICATIONS

This application is based upon and claims the benefit of priority from Japanese Patent Application No. 2013-233345, filed Nov. 11, 2013, the entire contents of which are incorporated herein by reference.

### FIELD

Embodiments described herein relate generally to a power supply device such as an AC/DC or DC/DC converter.

### BACKGROUND

AC/DC converters are widely used as power supply devices that convert, for example, a commercial AC input voltage of 100 V to a low DC output voltage which is suitable for electronic devices. An AC/DC converter comprises a main circuit board with a switching element circuit, power transformer, and cooling plate. Since the power transformer normally has a large volume and high thermal resistance, the cooling plate is configured to cool only the switching element circuit that has a low heat-resistant temperature.

In recent years, there has been a demand for smaller converters. If the component packaging density is increased to miniaturize the converters, heating of the power transformer greatly affects other components. Accordingly, the core of the transformer is made larger to improve the thermal radiation efficiency.

If this is done, however, the transformer is increased in size, and in addition, heat also flows into switching elements whose heat-resistant temperature is low, so that the cooling performance of the switching element circuit is reduced. Consequently, it is difficult to design small converters.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a perspective view showing an AC/DC converter according to a first embodiment;

FIG. 2 is an exploded perspective view of the AC/DC converter;

FIG. 3 is an exploded perspective view of the AC/DC converter taken in a direction opposite to FIG. 2;

FIG. 4 is a perspective view showing a main circuit board, transformer board, and intermediate cooling metal plate of the AC/DC converter;

FIG. 5 is a perspective view, partially in section, showing the main circuit board, transformer board, and intermediate cooling metal plate of the AC/DC converter;

FIG. 6 is a plan view of the main circuit board of the AC/DC converter;

FIG. 7 is a longitudinal sectional view of the AC/DC converter taken along line A-A of FIG. 1 with its case removed;

FIG. 8 is a cross-sectional view of the AC/DC converter taken along line B-B of FIG. 1;

FIG. 9 is an exploded perspective view of the transformer board;

FIG. 10 is a perspective view showing the intermediate cooling metal plate;

FIG. 11 is an exploded perspective view showing the intermediate cooling metal plate, a thermally conductive sheet, and a thermal insulation sheet; and

FIG. 12 is a perspective view schematically showing a ground portion of the intermediate cooling metal plate.

### DETAILED DESCRIPTION

Various embodiments will be described hereinafter with reference to the accompanying drawings. In general, according to one embodiment, a power supply device comprises a main circuit board comprising a switching circuit; a transformer board opposite the main circuit board and comprising a transformer; and an intermediate cooling plate between the main circuit board and the transformer board and configured to cool at least one of a heat-producing element of the switching circuit and the transformer.

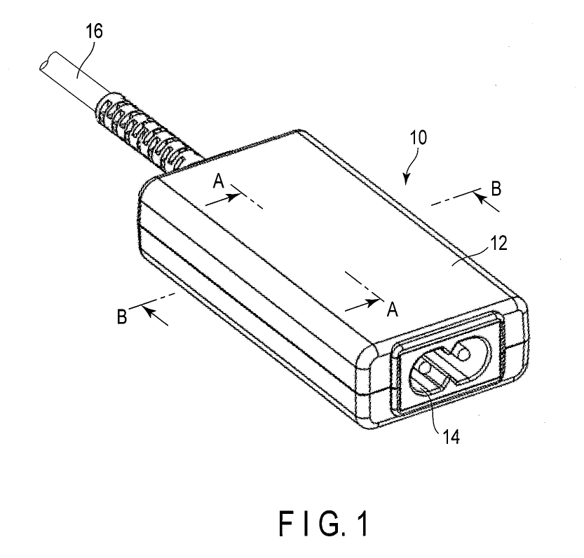

FIG. 1 is a perspective view showing an external appearance of a power supply device according to an embodiment. In this embodiment, the power supply device serves as, for example, an AC/DC converter 10, and in this case, is constructed as an AC adapter that can be connected to an electronic apparatus. The AC/DC converter 10 comprises a case 12 in the form of a flat rectangular box, input connector 14 connectable with an AC power supply, and output cable 16 for outputting a DC output voltage.

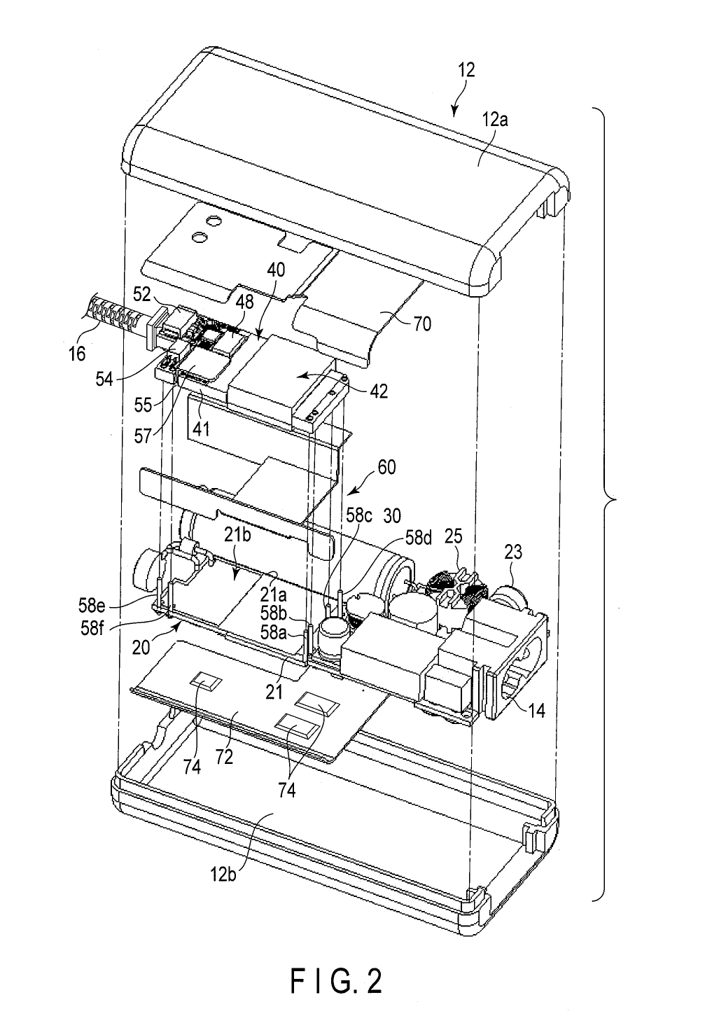

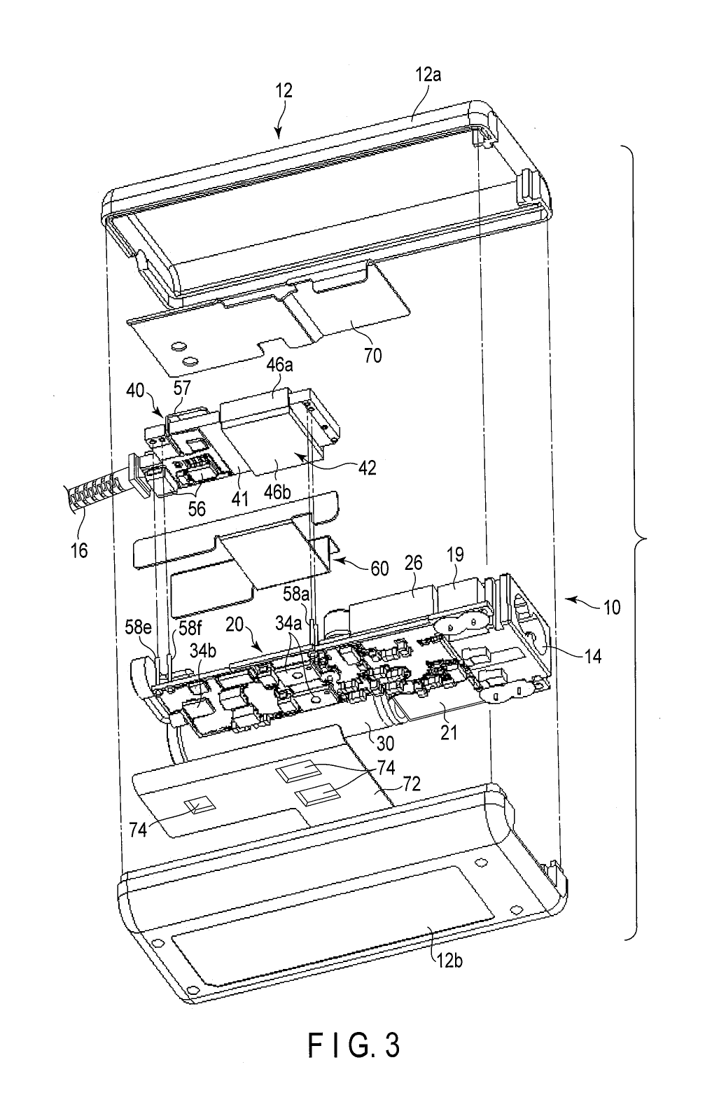

FIGS. 2 and 3 are exploded perspective views showing the internal structure of the AC/DC converter 10. As shown in these drawings, the case 12 comprises upper and lower cases 12a and 12b of, for example, a synthetic resin, which are separable from each other. The AC/DC converter 10 comprises a main circuit board 20, transformer board 40, intermediate cooling metal plate 60, upper cooling metal plate 70, and lower cooling metal plate 72. The main circuit board 20 comprises a switching circuit. The transformer board 40 is arranged opposite the main circuit board 20 and comprises a transformer 42. The intermediate cooling metal plate 60 is disposed between the main circuit board 20 and transformer board 40 and serves to cool a heat-producing element of the switching circuit and/or the transformer 42. The upper and lower cooling metal plates 70 and 72 are disposed overlapping the transformer board 40 and main circuit board 20, respectively. All these components are accommodated in the case 12.

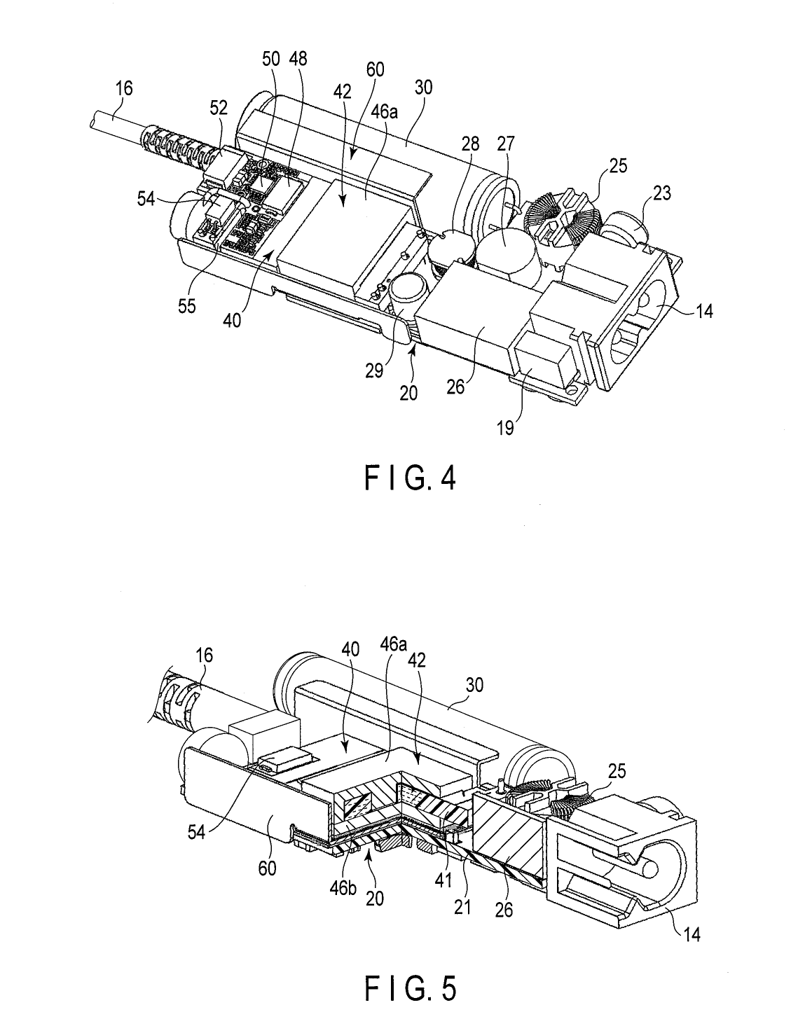

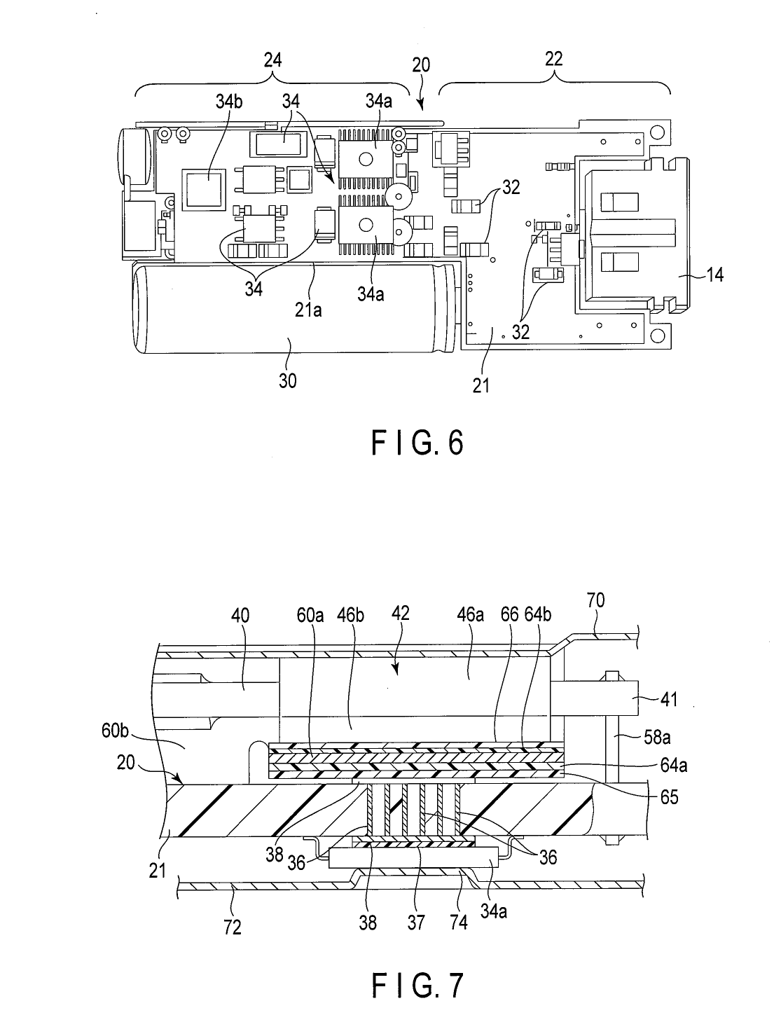

FIG. 4 is a perspective view showing the main circuit board 20, intermediate cooling metal plate 60, and transformer board 40 combined with one another, and FIG. 5 is a perspective view, partially in section, showing the main circuit board 20, intermediate cooling metal plate 60, and transformer board 40. FIG. 6 is a plan view showing the reverse side of the main circuit board 20.

As shown in FIGS. 2 to 6, the main circuit board 20 comprises a rectangular printed circuit board 21 and a plurality of primary electronic components mounted thereon. The printed circuit board 21 has a notch portion 21a in a part of it. The input connector 14 is mounted on one longitudinal end side of the main circuit board 20. The main circuit board 20 comprises an AC/DC converter circuit 22 and switching circuit (DC/AC converter circuit) 24. The AC/DC converter circuit 22 converts an input AC voltage input through the input connector 14 to a DC voltage. The switching circuit 24 converts the produced DC voltage to a high-frequency AC voltage.

On the side of the input connector 14, a fuse 19 and thermistor 23 are mounted on the upper surface of the main circuit board 20. The AC/DC converter circuit 22 comprises a choke coil 25, X-capacitor 26, diode bridge 27, choke coil 28, capacitor 29, and electrolytic capacitor 30. The choke coil 25 and X-capacitor 26 serve to reduce noise of the input AC voltage. The diode bridge 27 rectifies the AC voltage and produces a DC voltage. The choke coil 28 serves to reduce noise. The electrolytic capacitor 30 serves to smooth the rectified DC voltage. These electronic components are collectively mounted in an approximately half region of the upper surface of the main circuit board 20 on the side of the input connector 14. The electrolytic capacitor 30 is arranged in the notch portion 21a of the printed circuit board 21 and connected to the main circuit board 20.

An approximately half region of the upper surface of the main circuit board 20 on the opposite side to the input connector 14 forms a flat installation area 21b. The installation area 21b may hardly be mounted with any electronic components in some cases, and may be mounted with electronic components of a certain size or smaller in other cases. In the cases where the electronic components are mounted, it is necessary only that a thick cool sheet capable of absorbing irregularities of the mounting surface be sandwiched between the transformer board 40 and printed circuit board 21.

A plurality of semiconductor devices 32, which constitute the AC/DC converter circuit 22, and a plurality of semiconductor devices 34, which constitute the switching circuit 24, are mounted on the lower surface of the main circuit board 20. The semiconductor devices 32 are mounted in that region of the lower surface of the main circuit board 20 on the side of the input connector 14.

The semiconductor devices 34 that constitute the switching circuit 24 are mounted in an approximately half region of the lower surface of the main circuit board 20 on the opposite side to the input connector 14. These semiconductor devices 34 include a plurality (for example, two) of switching elements 34a and a control IC 34b for controlling the on-off timings of the switching elements 34a. For example, field-effect transistors (FETs), insulated-gate bipolar transistors (IGBTs), etc., are used as the switching elements 34a. Further, the two switching elements 34a are arranged substantially in the longitudinal center of the main circuit board 20.

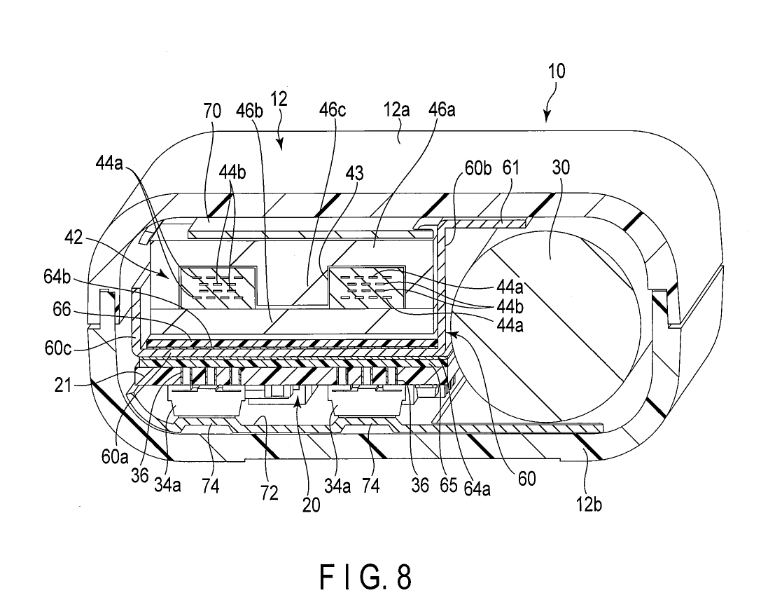

FIG. 7 is a longitudinal sectional view of the AC/DC converter taken along line A-A of FIG. 1, and FIG. 8 is a cross-sectional view of the AC/DC converter taken along line B-B of FIG. 1. In the present embodiment, as shown in FIGS. 7 and 8, a plurality of plated through-holes 36 are formed in the central portion of the main circuit board 20. Thermal pads 38 are provided individually on the upper and lower surfaces of the main circuit board 20 so as to face the plated through-holes 36. On the reverse side of the main circuit board 20, the switching elements 34a contact the plated through-holes 36 through a cool sheet 37 and one of the thermal pads 38.

The thermal pads 38 or cool sheet 37 may be omitted. Specifically, the switching elements 34a may be configured to contact the plated through-holes 36 directly or through the cool sheet 37, on the reverse side of the main circuit board 20.

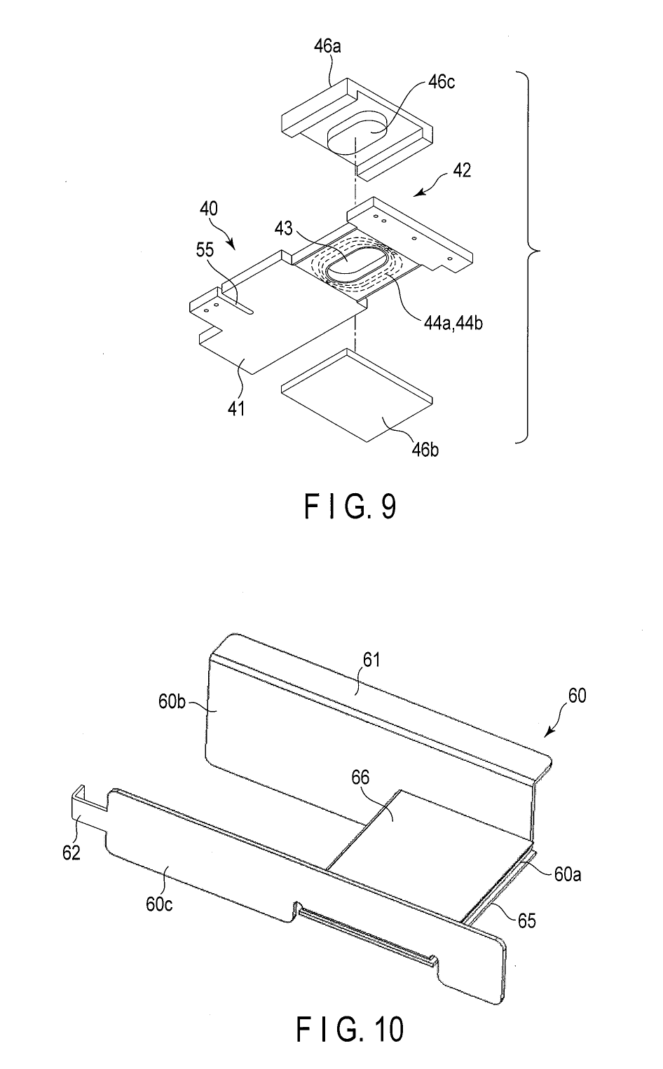

FIG. 9 is an exploded perspective view of the transformer board. As shown in FIGS. 2 to 5 and FIGS. 8 and 9, the transformer board 40 comprises a multi-layer printed circuit board 41, a plurality of secondary electronic components, and the planar transformer 42. The printed circuit board 41 comprises, for example, four or more electrically conductive layers. The secondary electronic components are mounted on the upper and lower surfaces of the printed circuit board 41. The transformer 42 is attached to the printed circuit board 41. The transformer board 40 is formed with a size smaller than (for example, about half or less) that of the main circuit board 20. An elongated through-hole 43 is formed in the transverse center of the printed circuit board 41.

The transformer 42 comprises primary coils 44a and secondary coils 44b, formed of the electrically conductive layers of the printed circuit board 41, and first and second transformer cores 46a and 46b each in the form of a rectangular plate. The primary and secondary coils 44a and 44b are provided on the printed circuit board 41 so that they are wound around the through-hole 43. In the present embodiment, the primary coils 44a are formed individually in the first and fourth electrically conductive layers of the printed circuit board 41, and the secondary coils 44b in the second and third electrically conductive layers, individually. Thus, the primary and secondary coils 44a and 44b are opposed thicknesswise relative to the printed circuit board 41. The turn ratio between the primary and secondary coils 44a and 44b is suitably set according to the transformation ratio of the transformer 42. The electrically conductive layers in which the primary and secondary coils 44a and 44b are formed are not limited to the above-described configuration.

The first and second transformer cores 46a and 46b are made of a magnetic material such as ferrite. The first transformer core 46a is an E-shaped core with an E-shaped cross-section and comprises a protrusion 46c in the center of its one side. The second transformer core 46b is an I-shaped core with an I-shaped cross-section or, in this case, a flat plate-shaped core.

The first transformer core 46a is disposed on the upper surface of the transformer board 40 in such a manner that the protrusion 46c penetrates the through-hole 43 of the transformer board 40. The second transformer core 46b is disposed on the lower surface of the transformer board 40 to face the through-hole 43 and is connected to the first transformer core 46a. Thus, the first and second transformer cores 46a and 46b cover the primary and secondary coils 44a and 44b from above and below, and the protrusion 46c penetrates the center of the coils 44a and 44b.

The primary and secondary coils 44a and 44b are magnetically connected to each other by the first and second transformer cores 46a and 46b. An AC voltage produced by the main circuit board 20 is input to the primary coils 44a, reduced by the transformer 42, and output from the secondary coils 44b.

As shown in FIGS. 2 to 4, the secondary electronic components mounted on the transformer board 40 include a diode 48, control IC 50, capacitor 52, and photo-coupler 54, which are mounted on the upper surface of the printed circuit board 41 so as to be kept at an insulation distance (creeping distance) from the transformer 42, a plurality of semiconductor devices 56 on the lower surface of the printed circuit board 41, etc. The diode 48 constitutes a rectifier circuit that rectifies the AC voltage output from the transformer 42 and produces a DC voltage. The capacitor 52 constitutes a smoothing circuit that smoothes the produced DC voltage. The smoothing circuit smoothes the DC voltage to produce a DC output voltage, which is supplied to the output cable 16.

The control IC 50 detects the output voltage and delivers a detection signal corresponding to the output voltage to the photo-coupler 54. The photo-coupler 54 comprises a light-emitting portion, which emits light on receiving the detection signal from the control IC 50, and a light-receiving portion facing the light-emitting portion with a gap between them. The light-receiving portion receives light corresponding to the detection signal from the light-emitting portion and outputs the detection signal to the control IC 34b of the main circuit board 20. An input terminal of the light-emitting portion and an output terminal of the light-receiving portion are spaced at a predetermined insulation distance from each other. In the printed circuit board 41, moreover, a slit 55 is formed near the photo-coupler 54, and an electrical insulation plate 57 is provided in the slit 55.

The transformer board 40 constructed in this manner is arranged so that its substantially entire lower surface faces the installation area 21b of the main circuit board 20 with a small gap from the upper surface of the main circuit board 20. A plurality of connecting pins 58a, 58b, 58c, 58d, 58e and 58f are set up on the main circuit board 20. These connecting pins are connected to and support the transformer board 40. Further, the connecting pins 58a to 58f electrically connect the main circuit board 20 and transformer board 40. More specifically, the connecting pins 58a to 58d electrically connect the output end of the switching circuit 24 of the main circuit board 20 and the primary coils 44a of the transformer board 40. Furthermore, the connecting pins 58e and 58f electrically connect the control IC 34b of the main circuit board 20 to the output terminal of the light-receiving portion of the photo-coupler 54 on the transformer board 40.

In the AC/DC converter 10 constructed in this manner, the AC/DC converter circuit 22 of the main circuit board 20 converts an input AC voltage of, for example, 100 V input through the input connector 14 to produce a DC voltage, which is supplied to the switching circuit 24. The switching circuit 24 switches the supplied DC voltage to produce a high-frequency AC voltage. The produced AC voltage is supplied to the transformer 42 of the transformer board 40, whereupon it is reduced to, for example, about 20 V by the transformer 42. The reduced AC voltage is rectified by the rectifier circuit on the transformer board 40, smoothed by the smoothing circuit, and output as a DC output voltage to the output cable 16. In order to keep the output voltage constant, moreover, the detection signal corresponding to the DC output voltage of the transformer board 40 is fed back from the control IC 50 to the control IC 34b of the main circuit board 20 through the photo-coupler 54. Based on this detection signal, the control IC 50 adjusts the switching of the switching elements 34a.

The following is a description of a cooling structure of the AC/DC converter 10. As shown in FIGS. 2, 3, 7 and 8, the AC/DC converter 10 comprises the upper, intermediate, and lower cooling metal plates 70, 60 and 72. The upper cooling metal plate 70 is disposed overlying the transformer board 40. The intermediate cooling metal plate 60 is interposed between the transformer board 40 and main circuit board 20. The lower cooling metal plate 72 is disposed covering the reverse side of the main circuit board 20. These cooling metal plates are made of a highly thermally conductive material, for example, copper, aluminum, etc.

The upper cooling metal plate 70 is in the form of a substantially flat rectangular plate, which covers the upper side of the transformer board 40 and a part of the main circuit board 20. A part of the upper cooling metal plate 70 is thermally connected to the first transformer core 46a of the transformer board 40 through a cool sheet or thermally conductive grease (hereinafter collectively referred to as a cool sheet or thermally conductive material) with good thermal conductivity. Thus, the upper cooling metal plate 70 can remove and release heat from the first transformer core 46a, thereby cooling the transformer board 40.

The lower cooling metal plate 72 is in the form of a substantially flat rectangular plate, which covers the lower side of the main circuit board 20. The lower cooling metal plate 72 comprises a plurality of projections 74 formed by drawing. These projections 74 are thermally connected through the cool sheet to heat-producing elements, that is, the switching elements 34a and control IC 34b in this case, which constitute the switching circuit 24. Thus, the lower cooling metal plate 72 can remove and outwardly release heat from the switching elements 34a and control IC 34b, thereby cooling the main circuit board 20.

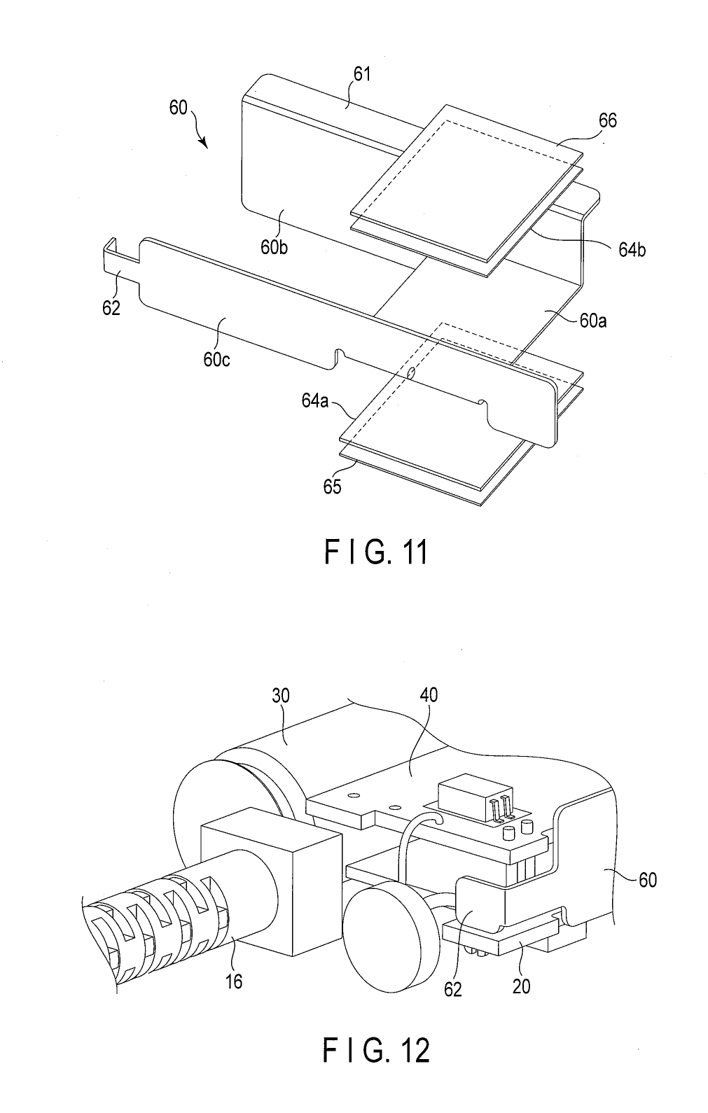

FIG. 10 is a perspective view of the intermediate cooling metal plate 60, FIG. 11 is an exploded perspective view showing the intermediate cooling metal plate, the cool sheet, a thermal insulation sheet, and an electrical insulation sheet, and FIG. 12 is a perspective view showing a ground portion of the intermediate cooling metal plate 60.

As shown in FIGS. 10 and 11, the intermediate cooling metal plate 60 is formed by bending a metallic plate and integrally comprises a rectangular, flat heat-receiving plate portion 60a in the center and a pair of heat sink portions 60b and 60c provided as fins on the opposite sides of the heat-receiving plate portion 60a. The heat-receiving plate portion 60a has an area slightly larger than that of the surface of each transformer core 46a, 46b. The heat sink portions 60b and 60c are bent substantially at right angles to the heat-receiving plate portion 60a and face each other with a gap therebetween. Further, a top portion 61 of the one heat sink portion 60b is outwardly bent at right angles and extends parallel to the heat-receiving plate portion 60a. A ground connecting portion 62 is integrally provided on one end of heat sink portion 60c.

A cool sheet (thermally conductive material) 65 is affixed to at least one surface of the heat-receiving plate portion 60a with an electrical insulation sheet 64a therebetween. Further, a cool sheet or thermal insulation sheet (heat insulating material) 66 is affixed to the other surface of the heat-receiving plate portion 60a with an electrical insulation sheet 64b therebetween.

If it is evaluated, for example, that the increased temperature of the transformer cores 46a, 46b can be fully reduced by the upper cooling metal plate 70 and that heat cannot be satisfactorily released from the switching circuit 24 by the lower cooling metal plate 72, the thermal insulation sheet 66 that contacts the second transformer core 46b is set on the upper surface of the heat-receiving plate portion 60a, while the cool sheet 65 that contacts the main circuit board 20 is set on the lower surface of the heat-receiving plate portion 60a.

As shown in FIGS. 2 to 5 and FIGS. 7 and 8, the intermediate cooling metal plate 60 is disposed in such a manner that its heat-receiving plate portion 60a is sandwiched between the second transformer core 46b of the transformer board 40 and the upper surface of the main circuit board 20 and that the pair of heat sink portions 60b and 60c laterally face the transformer board 40 and main circuit board 20. As shown in FIG. 12, the ground connecting portion 62 of the intermediate cooling metal plate 60 is electrically and mechanically connected to the ground of the main circuit board 20.

The upper surface side of the heat-receiving plate portion 60a contacts the second transformer core 46b with the electrical and thermal insulation sheets 64b and 66 therebetween. Further, the lower surface side of the heat-receiving plate portion 60a contacts the thermal pad 38 on the upper surface of the main circuit board 20 with the electrical insulation sheet 64a and cool sheet 65 therebetween. In this way, the heat-receiving plate portion 60a is thermally connected to the switching elements 34a through the upper thermal pad 38, plated through-holes 36, and lower thermal pad 38. Thus, the intermediate cooling plate 60 removes heat from the switching elements 34a through the thermal pad 38 and outwardly releases heat through heat sink portions 60b and 60c, thereby cooling the switching elements.

According to the AC/DC converter 10 constructed in this manner, the two-board configuration is provided comprising the transformer board with the planar transformer and the main circuit board mounted with the switching elements, and the intermediate cooling plate is interposed between the two boards. The thermally conductive sheet and thermal insulating material are affixed individually to the opposite surfaces of the intermediate cooling plate so that the power supply can be miniaturized by positively cooling the switching device circuit having a low heat-resistant temperature. By adjusting the thermally conductive sheet or thermal insulation sheet affixed to the intermediate cooling plate, the cooling ratio can be easily controlled according to the heat production rates of the planar transformer and switching elements that are different in heat-resistant temperature. Cooling of the transformer cores and switching elements can be prioritized without substantially changing the construction, and an optimal cooling structure can be provided by slightly changing the design as trial production is replaced by mass production. Thus, there can be provided an AC/DC converter capable of being easily miniaturized while maintaining high cooling performance.

If it is evaluated that the temperature increase of the transformer cores is too great to be fully reduced by cooling by means of the upper cooling metal plate 70 and that heat can be satisfactorily released from the switching circuit by the lower cooling metal plate 72, a cool sheet (heat transfer sheet) may be affixed to the upper surface side of the heat-receiving plate portion 60a of the intermediate cooling metal plate 60 so that the heat-receiving plate portion and transformer cores are thermally connected by the cool sheet. Alternatively, a thermal insulation sheet may be affixed to the lower surface side of heat-receiving plate portion 60a so that the heat-receiving plate portion and main circuit board are thermally insulated from each other.

If necessary, moreover, cool sheets may be provided individually on the opposite surface sides of the heat-receiving plate portion of the intermediate cooling metal plate. In this case, furthermore, cool sheets (thermally conductive material) with different areas may be affixed individually to the heat-receiving plate portion so that the distribution of heat transfer on the upper surface side is different from that on the lower surface side.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the AC/DC converter is not limited to an adapter and may alternatively be configured to be installed in the electronic apparatus. The shapes, sizes, and forming materials of the constituent members of the AC/DC converter are not limited to the embodiments and may be variously changed.

What is claimed is:

1. A power supply device comprising:
a main circuit board comprising a switching circuit;
a transformer board opposite the main circuit board and comprising a transformer; and
an intermediate cooling plate between the main circuit board and the transformer board and configured to cool at least one of the transformer or a heat-producing element of the switching circuit or combination thereof.

2. The power supply device of claim 1, wherein the intermediate cooling plate comprises a heat-receiving plate portion between the transformer and the main circuit board and a heat sink portion extending outwardly relative to the main circuit board, and at least one surface of the heat-receiving plate portion is thermally connected to the transformer or the main circuit board through a thermally conductive material.

3. The power supply device of claim 2, wherein the thermally conductive material is provided on either surface of the heat-receiving plate portion.

4. The power supply device of claim 2, wherein a heat insulating material is provided on another surface of the heat-receiving plate portion.

5. The power supply device of claim 2, further comprising an upper cooling plate overlapping the transformer board and a lower cooling metal plate overlapping the main circuit board.

6. The power supply device of claim 5, wherein the transformer is configured to be a planar transformer comprising a primary coil and a secondary coil provided in the transformer board and a plate-shaped transformer core on the transformer board so as to overlap the primary and secondary coils.

7. The power supply device of claim 6, wherein the heat-receiving plate portion of the intermediate cooling plate opposes the transformer core.

8. The power supply device of claim 1, further comprising an upper cooling plate overlapping the transformer board and a lower cooling metal plate overlapping the main circuit board.

9. The power supply device of claim 8, wherein the transformer is configured to be a planar transformer comprising a primary coil and a secondary coil provided in the transformer board and a plate-shaped transformer core on the transformer board so as to overlap the primary and secondary coils.

10. The power supply device of claim 9, wherein the intermediate cooling plate comprises a heat-receiving plate portion opposed to the transformer core.

11. The power supply device of claim 1, wherein the transformer is configured to be a planar transformer comprising a primary coil and a secondary coil provided in the transformer board and a plate-shaped transformer core on the transformer board so as to overlap the primary and secondary coils.

12. The power supply device of claim 11, wherein the intermediate cooling plate comprises a heat-receiving plate portion opposed to the transformer core.
